(19) United States
(12) Patent Application Publication
(10) Pub. No.: US 2025/0107099 A1
(43) Pub. Date: Mar. 27, 2025

(54) SEMICONDUCTOR MEMORY DEVICE

(71) Applicant: Samsung Electronics Co., Ltd., Suwon-si (KR)

(72) Inventor: Hyeran Lee, Suwon-si (KR)

(21) Appl. No.: 18/657,970

(22) Filed: May 8, 2024

(30) Foreign Application Priority Data
Sep. 21, 2023 (KR) 10-2023-0126569

(51) Int. Cl. H10B 51/20; H01L 23/522; H01L 23/528; H01L 29/78; H10B 12/00; H10B 53/20

(52) U.S. Cl. CPC H10B 51/20; H01L 23/5226; H01L 23/5283; H10B 12/315; H10B 12/482; H10B 12/485; H10B 12/488; H10B 53/20; H10D 30/701

(57) ABSTRACT

A semiconductor device includes a first substrate and first and second memory blocks on the first substrate and spaced apart in a first direction, the first memory block includes first bit lines spaced apart in a second direction, first semiconductor patterns in contact with side surfaces of the first bit lines and extending in a direction, and first capacitors electrically connected to ends of the first semiconductor patterns, the second memory block includes second bit lines spaced apart in the second direction, second semiconductor patterns in contact with side surfaces of the second bit lines and extending in the first direction, and second capacitors electrically connected to ends of the second semiconductor patterns. The first capacitors respectively include a first dielectric layer of one of silicon oxide or metal oxide, and the second capacitors respectively include a second dielectric layer of one of ferroelectric or antiferroelectric materials.

### CROSS-REFERENCE TO RELATED APPLICATIONS

This U.S. non-provisional patent application claims priority under 35 U.S.C. § 119 to Korean Patent Application No. 10-2023-0126569, filed on Sep. 21, 2023, in the Korean Intellectual Property Office, the entire contents of which are hereby incorporated by reference.

### FIELD

The inventive concept relates to a semiconductor memory device.

### BACKGROUND

Semiconductor devices may be attractive in the electronic industry because of their relatively small size, multi-functional characteristics and/or relatively low fabrication cost. As electronic devices become more highly integrated, semiconductor devices have likewise become more highly integrated. The line widths of the semiconductor devices have been gradually reduced to increase the integration density of the semiconductor devices. However, there may be some limitations in increasing the integration density of the semiconductor devices, for example, as new exposure techniques and/or high cost for the new exposure techniques may be required in order to provide further reduction of the line widths.

### SUMMARY

Embodiments of the inventive concept provide a highly integrated semiconductor memory device that has both volatile and non-volatile characteristics.

A semiconductor memory device according to some embodiments of the inventive concept includes a first substrate and a first memory block and a second memory block on an upper surface of the first substrate and spaced apart from each other in a first direction, wherein the first memory block includes first bit lines extending perpendicular to the upper surface of the first substrate, the first bit lines being spaced apart from each other in a second direction intersecting the first direction, first semiconductor patterns in contact with side surfaces of the first bit lines, the first semiconductor patterns extending in the first direction, and first capacitors electrically connected to ends of the first semiconductor patterns, the second memory block includes second bit lines extending perpendicular to the upper surface of the first substrate, the second bit lines being spaced apart from each other in the second direction, second semiconductor patterns in contact with side surfaces of the second bit lines, the second semiconductor patterns extending in the first direction, and second capacitors electrically connected to ends of the second semiconductor patterns, wherein the first capacitors respectively include a first dielectric layer of at least one of silicon oxide or metal oxide, and the second capacitors respectively include a second dielectric layer of at least one of a ferroelectric material or an antiferroelectric material.

A semiconductor memory device according to some embodiments of the inventive concept includes a first substrate, a first memory block and a second memory block on an upper surface of the first substrate and spaced apart from each other in a first direction, and transfer transistors on the first substrate and electrically connecting the first memory block to the second memory block, wherein the first memory block includes first bit lines extending perpendicular to the upper surface of the first substrate, the first bit lines being spaced apart from each other in a second direction intersecting the first direction, first semiconductor patterns in contact with side surfaces of the first bit lines, the first semiconductor patterns extending in the first direction, and first capacitors electrically connected to ends of the first semiconductor patterns, the second memory block includes second bit lines extending perpendicular to the upper surface of the first substrate, the second bit lines being spaced apart from each other in the second direction, second semiconductor patterns in contact with side surfaces of the second bit lines, the second semiconductor patterns extending in the first direction, and second capacitors electrically connected to ends of the second semiconductor patterns, wherein the first capacitors respectively include a first dielectric layer of at least one of silicon oxide or metal oxide, and the second capacitors respectively include a second dielectric layer of at least one of a ferroelectric material or an antiferroelectric material.

A semiconductor memory device according to some embodiments of the inventive concept includes a first substrate, a first memory block and a second memory block on an upper surface of the first substrate and spaced apart from each other in a first direction, transfer transistors on the first substrate and electrically connecting the first memory block to the second memory block, a second substrate on the first memory block and the second memory block, and bit line selection transistors on the second substrate and electrically connected to the first bit lines, wherein the first memory block includes first bit lines extending perpendicular to the upper surface of the first substrate, the first bit lines being spaced apart from each other in a second direction intersecting the first direction, first semiconductor patterns in contact with side surfaces of the first bit lines, the first semiconductor patterns extending in the first direction, first word lines adjacent upper surfaces of the first semiconductor patterns, a first gate insulating layer between the first semiconductor patterns and the first word lines, and first capacitors electrically connected to ends of the first semiconductor patterns, the second memory block includes second bit lines extending perpendicular to the upper surface of the first substrate, the second bit lines being spaced apart from each other in the second direction, second semiconductor patterns in contact with side surfaces of the second bit lines, the second semiconductor patterns extending in the first direction, second word lines adjacent upper surfaces of the second semiconductor patterns, a second gate insulating layer between the second semiconductor patterns and the second word lines; and second capacitors electrically connected to ends of the second semiconductor patterns, wherein the first capacitors respectively include a first dielectric layer of at least one of silicon oxide or metal oxide, and the second capacitors respectively include a second dielectric layer of at least one of a ferroelectric material or an antiferroelectric material.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram of a semiconductor memory device according to embodiments of the inventive concept.

FIG. 2 is a perspective view of a semiconductor memory device according to embodiments of the inventive concept.

FIG. 3 is a cross-sectional view taken along line A-A′ of FIG. 2 according to embodiments of the inventive concept.

FIG. 4 is an enlarged view of potion ‘P1’ of FIG. 3.

FIGS. 5A and 5B are enlarged views of portion ‘P2’ of FIG. 3.

FIGS. 6A, 6B, 6C, 6D, 6E, and 6F sequentially illustrate a process of manufacturing the semiconductor memory device of FIG. 3.

FIG. 7 is a cross-sectional view of a semiconductor memory device according to embodiments of the inventive concept.

FIG. 8 is a cross-sectional view of a semiconductor memory device according to embodiments of the inventive concept.

### DETAILED DESCRIPTION OF EMBODIMENTS

Hereinafter, to explain the inventive concept in detail, embodiments according to the inventive concept will be described in detail with reference to the accompanying drawings. In this specification, ‘word line’ may be referred to as ‘first conductive line’, and ‘bit line’ may be referred to as ‘second conductive line’. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

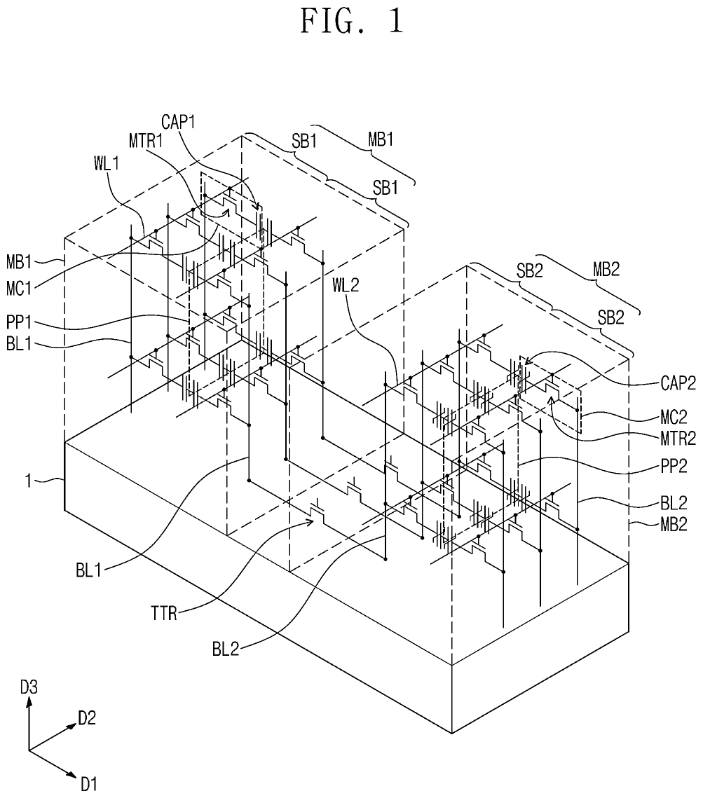

FIG. 1 is a circuit diagram of a semiconductor memory device according to embodiments of the inventive concept.

Referring to FIG. 1, a semiconductor memory device according to the present embodiment may be, for example, hybrid random access memory (HRAM), which is a combination of dynamic random access memory (DRAM) and ferroelectric random access memory (FeRAM). Specifically, the semiconductor memory device includes a first memory block MB1 and a second memory block MB2 disposed on a first substrate 1 and spaced apart from each other in a first direction D1. The first direction D1 may be parallel to an upper surface of the first substrate 1.

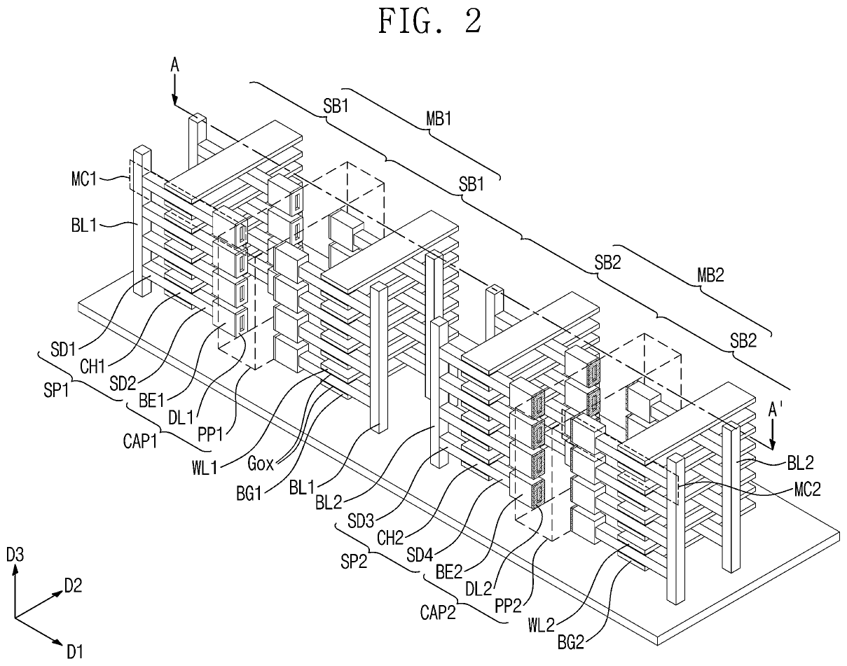

The first memory block MB 1 may be a DRAM cell block. The first memory block MB1 includes first sub-blocks SB1 that are symmetrical to each other about a first common electrode PP1. The first sub-blocks SB1 include first memory cells MC1 arranged in a second direction D2 and a third direction D3. The second direction D2 may be parallel to the upper surface of the first substrate 1 and may intersect the first direction D1. The third direction D3 may be perpendicular to the upper surface of the first substrate 1. The first memory cells MC1 may be DRAM cells. One first memory cell MC1 may include one first memory transistor MTR1 and a first capacitor CAP1 connected to one end thereof. The first capacitor CAP1 may have a first dielectric layer DL1 (of FIG. 2) having a single-layer or multi-layer structure of at least one of silicon oxide and metal oxide. A gate of the first memory transistor MTR1 is connected to a first word line WL1. A first bit line BL1 is connected to the other terminal of the first memory transistor MTR1. The first memory block MB1 may include DRAM cells and may have volatile memory storage characteristics, to enable fast data processing and have excellent durability.

The second memory block MB2 may be a FeRAM cell block. The second memory block MB2 includes second sub-blocks SB2 that are symmetrical to each other about a second common electrode PP2. The second sub-blocks SB2 include second memory cells MC2 arranged in the second direction D2 and the third direction D3. The second memory cells MC2 may be FeRAM cells. One second memory cell MC2 may include one second memory transistor MTR2 and a second capacitor CAP2 connected to one end thereof. The second capacitor CAP2 may have a second dielectric layer DL2 (of FIG. 2) having a single-layer or multi-layer structure of at least one of a ferroelectric material or an anti-ferroelectric material. A gate of the second memory transistor MTR2 is connected to a second word line WL2. A second bit line BL2 is connected to the other terminal of the second memory transistor MTR2. Ferroelectric or antiferroelectric materials may have polarization direction thereof changed by an electric field. As the polarization direction pinned to one side does not change even when the voltage is turned off, the FeRAM cells may have non-volatile memory storage characteristics. Additionally, the FeRAM cells have excellent power gain characteristics.

The first memory block MB1 may be connected to the second memory block MB2 through transfer transistors TTR. That is, the first bit lines BL1 belonging to one first sub-block SB1 may be connected to the second bit lines BL2 belonging to the second sub-block SB2 adjacent to the first sub-block SB1, by the transfer transistors TTR.

Although not shown in FIG. 1, the first bit lines BL1 of the first memory block MB1 and/or the second bit lines BL2 of the second memory block MB2 may be connected to a sense amplifier circuit or a bit line selection circuit. The first word lines WL1 of the first memory block MB1 and the second word lines WL2 of the second memory block MB2 may be connected to a sub-word line driver circuit or a row decoder circuit.

According to one example, the first bit lines BL1 of the first memory block MB1 may be connected to the sense amplifier circuit or the bit line selection circuit, but the second bit lines BL2 of the second memory block MB2 may not be connected to the sense amplifier circuit or the bit line selection circuit. In this case, when performing a program/read operation on the first memory block MB1, the transfer transistors TTR may be turned off. When performing a program/read operation on the second memory block MB2, the transfer transistors TTR may be turned on and a turn-off voltage may be applied to the first word lines WL1 of the first memory block MB1.

The semiconductor memory device according to the present embodiment may include both the first memory block MB1 including the DRAM cells and the second memory block MB2 including the FeRAM cells, thereby having both advantages of DRAM and FeRAM. The semiconductor memory device having the circuit diagram of FIG. 1 may be embodied as follows.

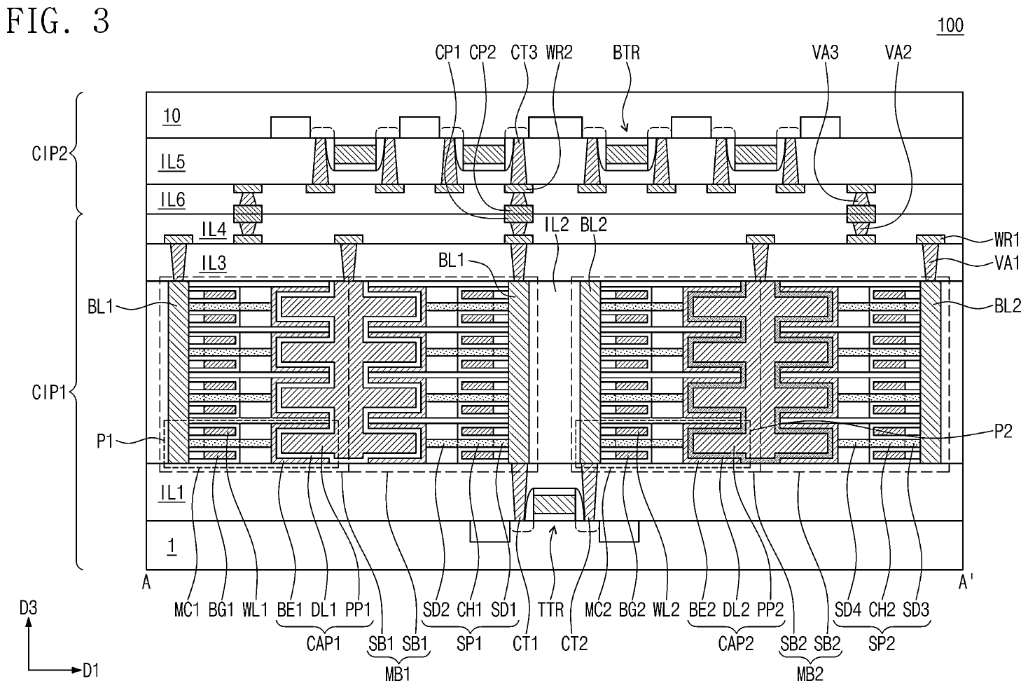

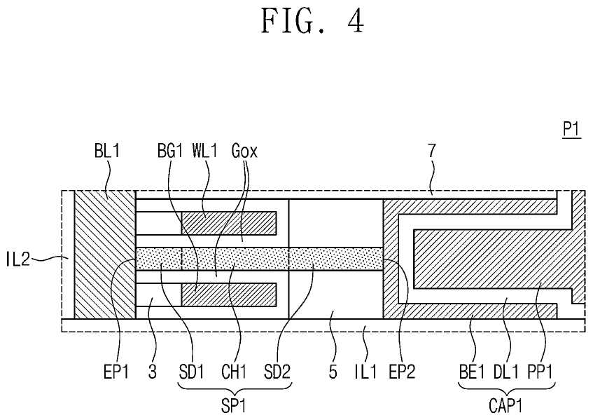

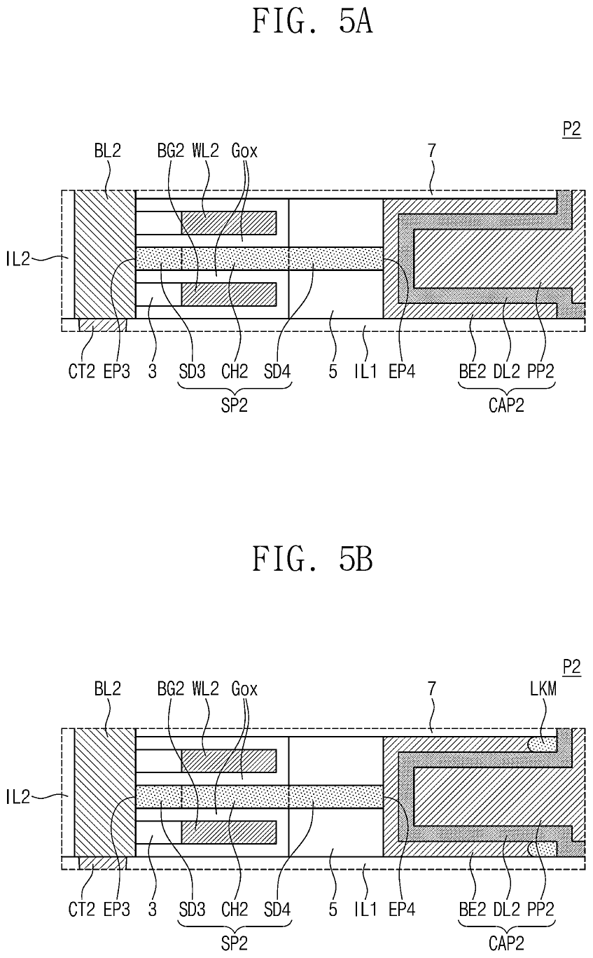

FIG. 2 is a perspective view of a semiconductor memory device according to embodiments of the inventive concept. FIG. 3 is a cross-sectional view taken along line A-A′ of FIG. 2 according to embodiments of the inventive concept. FIG. 4 is an enlarged view of potion ‘P1’ of FIG. 3. FIGS. 5A and 5B are enlarged views of portion ‘P2’ of FIG. 3.

Referring to FIGS. 2 and 3, a semiconductor memory device 100 according to the present embodiment includes a first semiconductor chip CIP1 and a second semiconductor chip CIP2 bonded thereon. The first semiconductor chip CIP1 includes a first substrate 1, a first memory block MB1 and a second memory block MB2 disposed thereon, and first to fourth interlayer insulating layers IL1, IL2, IL3, and IL4. The first memory block MB1 and the second memory block MB2 may have the same structure except for differences in materials of first and second dielectric layers DL1 and DL2. The first memory block MB1 and the second memory block MB2 may have a symmetrical structure with respect to the second interlayer insulating layer IL2 interposed therebetween.

The first substrate 1 may include a semiconductor material. A transfer transistor TTR may be disposed on the first substrate 1. The transfer transistor TTR may include a transfer gate and source/drain regions disposed on both (e.g., opposing) sides of the transfer gate. The transfer transistor TTR and the first substrate 1 may be covered with the first interlayer insulating layer IL1. Each of the first to fourth interlayer insulating layers IL1 to IL4 may have a single-layer or multi-layer structure of at least one of silicon oxide, silicon nitride, silicon oxynitride, SiCN, and low-k porous insulator.

A first contact CT1 and a second contact CT2 are disposed in the first interlayer insulating layer IL1. The first contact CT1 may connect one terminal (one of the source/drain regions) of the transfer transistor TTR to a first bit line BL1 of the first memory block MB1. The second contact CT2 may connect the other terminal (the other one of the source/drain regions) of the transfer transistor TTR to a second bit line BL2 of the second memory block MB2.

Referring to FIGS. 2, 3, and 4, the first memory block MB1 and a second memory block MB2 are disposed on the first interlayer insulating layer IL1. The second interlayer insulating layer IL2 is disposed between the first memory block MB1 and the second memory block MB2. The first memory block MB1 includes first memory cells MC1 arranged three-dimensionally in the first to third directions D1 to D3. The second memory block MB2 includes second memory cells MC2 arranged three-dimensionally in the first to third directions D1 to D3.

The first memory block MB1 includes first sub-blocks SB1 that are symmetrical to each other about a first common electrode PP1. The first memory block MB1 includes first semiconductor patterns SP1 stacked on the first interlayer insulating layer IL1. Each of the first semiconductor patterns SP1 may have a bar shape elongated in the first direction D1. The first semiconductor patterns SP1 may include at least one of single crystal silicon, polysilicon, oxide semiconductor, and two-dimensional material. The oxide semiconductor may be, for example, indium gallium zinc oxide (IGZO). The two-dimensional material may be MoS₂, WS₂, MoSc₂, or WSe₂. The first semiconductor patterns SP1 may include a first channel region CH1 at a center or central region thereof and first and second source/drain regions SD1 and SD2 on both (e.g., opposing) sides thereof. The first and second source/drain regions SD1 and SD2 may be doped with impurities of a first conductivity type.

Each of the first semiconductor patterns SP1 has a first end EP1 and a second end EP2 that are opposite to each other. The first ends EP1 of the first semiconductor patterns SP1 may be ends of the first source/drain region SD1. First ends EP1 of the first semiconductor patterns SP1 may be in contact with the first bit lines BL1. The first bit lines BL1 may be in contact with an upper surface of the first interlayer insulating layer IL1 and may extend from the upper surface thereof in a vertical third direction D3. Second ends EP2 of the first semiconductor patterns SP1 may be ends of the second source/drain region SD2. The second ends EP2 of the first semiconductor patterns SP1 may be in contact with a first capacitor CAP1.

The first capacitor CAP1 may include a first unit electrode BE1, a first dielectric layer DL1, and a first common electrode PP1. The first unit electrode BE1 and the first common electrode PP1 may include metals such as tungsten, aluminum, titanium, tantalum, and ruthenium, respectively. The first dielectric layer DL1 may have a single-layer or multi-layer structure of at least one of silicon oxide and metal oxide. The metal oxide may include at least one of aluminum oxide, hafnium oxide, and zirconium oxide. The first unit electrode BE1 may have a hollow cup shape or cylindrical shape that is closed at one end. A portion of the first dielectric layer DL1 and first common electrode PP1 may be inserted or may otherwise extend into the first unit electrode BE1.

The first word line WL1 may be disposed on a first channel region CHI of first semiconductor patterns SP1. The first word line WL1 may extend in the second direction D2. The first word lines WL1 may be stacked in the third direction D3. Although not shown, ends of the first word lines WL1 may have a step shape. A gate insulating layer Gox may be interposed between the first semiconductor patterns SP1 and the first word lines WL1.

One first semiconductor pattern SP1 and a portion of the first word line WL1 passing thereon may compose a first memory transistor MTR1 of FIG. 1. The first memory transistor MTR1 and the first capacitor CAP1 connected to the first semiconductor pattern SP1 may compose one first memory cell MC1.

A first back gate line BG1 may be disposed below the first channel region CH1 of the first semiconductor patterns SP1. The first back gate line BG1 may extend in the second direction D2. The first back gate lines BG1 may be stacked in the third direction D3. Although not shown, ends of the first back gate lines BG1 may have a step shape. The gate insulating layer Gox may be interposed between the first semiconductor patterns SP1 and the first back gate lines BG1. The first back gate line BG1 may adjust a threshold voltage of the first memory transistor MTR1.

Referring to FIGS. 2, 3, 5A, and 5B, the second memory block MB2 includes second sub-blocks SB2 that are symmetrical to each other about a second common electrode PP2. The second memory block MB2 includes second semiconductor patterns SP2 stacked on the first interlayer insulating layer IL1. Each of the second semiconductor patterns SP2 may have a bar shape elongated in the first direction D1. The second semiconductor patterns SP2 may include at least one of single crystal silicon, polysilicon, oxide semiconductor, and two-dimensional material. The second semiconductor patterns SP2 may include a second channel region CH2 at a center or central region thereof and third and fourth source/drain regions SD3 and SD4 on both (e.g., opposing) sides of the second channel region CH2. The third and fourth source/drain regions SD3 and SD4 may be doped with impurities of the first conductivity type.

Each of the second semiconductor patterns SP2 has third and fourth ends EP3 and EP4 that are opposite to each other. The third ends EP3 of the second semiconductor patterns SP2 may be ends of the third source/drain region SD3. The third ends EP3 of the second semiconductor patterns SP2 may be in contact with a second bit lines BL2. The second bit lines BL2 may be in contact with the upper surface of the first interlayer insulating layer IL1 and may extend from an upper surface in the third direction D3 perpendicular to the upper surface thereof. The fourth ends EP4 of the second semiconductor patterns SP2 may be ends of the fourth source/drain region SD4. The fourth ends EP4 of the second semiconductor patterns SP2 may be in contact with a second capacitor CAP2.

Referring to FIG. 5A, the second capacitor CAP2 may include a second unit electrode BE2, a second dielectric layer DL2, and a second common electrode PP2. The second unit electrode BE2 and the second common electrode PP2 may include metals such as tungsten, aluminum, titanium, tantalum, and ruthenium, respectively. The second dielectric layer DL2 may include a single-layer or multi-layer structure of at least one of a ferroelectric material and an antiferroelectric material. The ferroelectric material may be at least one of HfO₂, ZrO₂, HfₓZr₁₋ₓO₂, BaTiO₃, SrTiO₃, and SrₓBa₁₋ₓTiO₃, the antiferroelectric material may be at least one of ZrO₂, Hf_{y}Zr_{1-y}O₂, PbZrO₃, and AgNbO₃, in which ‘x’ is 0.5 or more, and ‘y’ is less than 0.5. The second dielectric layer DL2 may have a thickness of 30 to 100 Å. The second unit electrode BE2 may have a hollow cup shape. A portion of the second dielectric layer DL2 and second common electrode PP2 may be inserted or may otherwise extend into the second unit electrode BE2.

Referring to FIG. 5B, ends of the second unit electrode BE2 may include a leaker material portion LKM. The leaker material portion LKM may include a leaker material. An electrical resistance of the leaker material may be greater than an electrical resistance of the conductive material constituting the second unit electrode BE2 and may be smaller than an electrical resistance of the ferroelectric material or the antiferroelectric material. The leaker material portion LKM may prevent overload of the second capacitor CAP2 when charge is accumulated in the second capacitor CAP2.

A second word line WL2 may be disposed on the second channel region CH2 of the second semiconductor patterns SP2. The second word line WL2 may extend in the second direction D2. The second word lines WL2 may be stacked in the third direction D3. Although not shown, ends of the second word lines WL2 may have a step shape. The gate insulating layer Gox may be interposed between the second semiconductor patterns SP2 and the second word lines WL2.

One second semiconductor pattern SP2 and a portion of the second word line WL2 passing thereon may compose a second memory transistor MTR2 of FIG. 1. The second memory transistor MTR2 and the second capacitor CAP2 connected to the second semiconductor pattern SP2 may compose one second memory cell MC2.

A second back gate line BG2 may be disposed below the second channel region CH2 of the second semiconductor patterns SP2. The second back gate line BG2 may extend in the second direction D2. The second back gate lines BG2 may be stacked in the third direction D3. Although not shown, ends of the second back gate lines BG2 may have a step shape. The gate insulating layer Gox may be interposed between the second semiconductor patterns SP2 and the second back gate lines BG2. The second back gate line BG2 may adjust a threshold voltage of the second memory transistor MTR2.

Referring to FIGS. 4, 5A, and 5B, a first insulating pattern 3 may be interposed between the first and second word lines WL1 and WL2 and the first and second bit lines BL1 and BL2, and between the first and second back gate lines BG1 and BG2 and the first and second bit lines BL1 and BL2. A second insulating pattern 5 may be interposed between the first and second word lines WL1 and WL2 and the first and second unit electrodes BE1 and BE2, and between the first and second back gate lines BG1 and BG2 and the first and second unit electrodes BE1 and BE2. A third insulating pattern 7 may be interposed between the first unit electrodes BE1 and the second unit electrodes BE2. The first to third insulating patterns 3, 5, and 7 may each independently have a single-layer or multi-layer structure of at least one of silicon oxide, silicon nitride, and silicon oxynitride. The gate insulating layer Gox may cover side surfaces of the first and second word lines WL1 and WL2 and may cover upper and lower surfaces of the first and second word lines WL1 and WL2 and the first insulating patterns 3. The third insulating pattern 7 may cover an upper surface of the gate insulating layer Gox. The term “cover” or “surround” or “fill” as may be used herein may not require completely covering or surrounding or filling the described elements or layers, but may, for example, refer to partially surrounding or covering or filling the described elements or layers, for example, with voids or other spaces throughout.

A third interlayer insulating layer IL3 and a fourth interlayer insulating layer IL4 are sequentially stacked on the first and second memory blocks MB1 and MB2 and the second interlayer insulating layer IL2. First vias VA1 may be disposed in the third interlayer insulating layer IL3. First wirings WR1 are disposed between the third interlayer insulating layer IL3 and the fourth interlayer insulating layer IL4. Second vias VA2 are disposed in the fourth interlayer insulating layer IL4. First conductive pads CP1 are disposed on the fourth interlayer insulating layer IL4. Each of the first vias VA1, first wirings WR1, second vias VA2, and first conductive pads CP1 may include a metal such as tungsten, copper, aluminum, ruthenium, tantalum, and titanium.

The second semiconductor chip CIP2 includes a second substrate 10 and bit line selection transistors BTR disposed on a lower surface thereof. The bit line selection transistors BTR may compose a sense amplifier circuit or a bit line select circuit. The lower surface of the second substrate 10 may be sequentially covered with fifth and sixth interlayer insulating layers IL5 and IL6. Each of the fifth and sixth interlayer insulating layers IL5 and IL6 may have a single-layer or multi-layer structure of at least one of silicon oxide, silicon nitride, silicon oxynitride, SiCN, and low-k porous insulator.

Third contacts CT3 are disposed in the fifth interlayer insulating layer IL5. Second wirings WR2 are disposed between the fifth and sixth interlayer insulating layers IL5 and IL6. Third vias VA3 are disposed in the sixth interlayer insulating layer IL6. Second conductive pads CP2 are disposed at the bottom of the sixth interlayer insulating layer IL6. Each of the third contacts CT3, second wirings WR2, third vias VA3, and second conductive pads CP2 may include a metal such as tungsten, copper, aluminum, ruthenium, tantalum, and titanium.

The fourth interlayer insulating layer IL4 of the first semiconductor chip CIP1 may be in contact with the sixth interlayer insulating layer IL6 of the second semiconductor chip CIP2. The second conductive pads CP2 of the second semiconductor chip CIP2 may be in contact with the first conductive pads CP1 of the first semiconductor chip CIP1, respectively. A lower portion of one of the first bit lines BL1 may be in contact with the first contact CT1, and an upper portion of the one of the first bit lines BL1 may be connected to one terminal of the bit line selection transistor BTR, through the first via VA1, first wiring WR1, second via VA2, first conductive pad CP1, second conductive pad CP2, third via VA3, second wiring WR2, and third contact CT3.

The semiconductor memory device 100 according to the inventive concept has a three-dimensional structure, is highly integrated, and it is easy to manufacture the same.

In this semiconductor memory device, the first and second back gate lines BG1 and BG2 may be omitted. Alternatively, the first and second back gate lines BG1 and BG2 may be combined with the first and second word lines WL1 and WL2, respectively, thereby providing the first and second word lines WL1 and WL2 of a gate-all-around (GAA) structure surrounding the first and second channel regions CH1 and CH2.

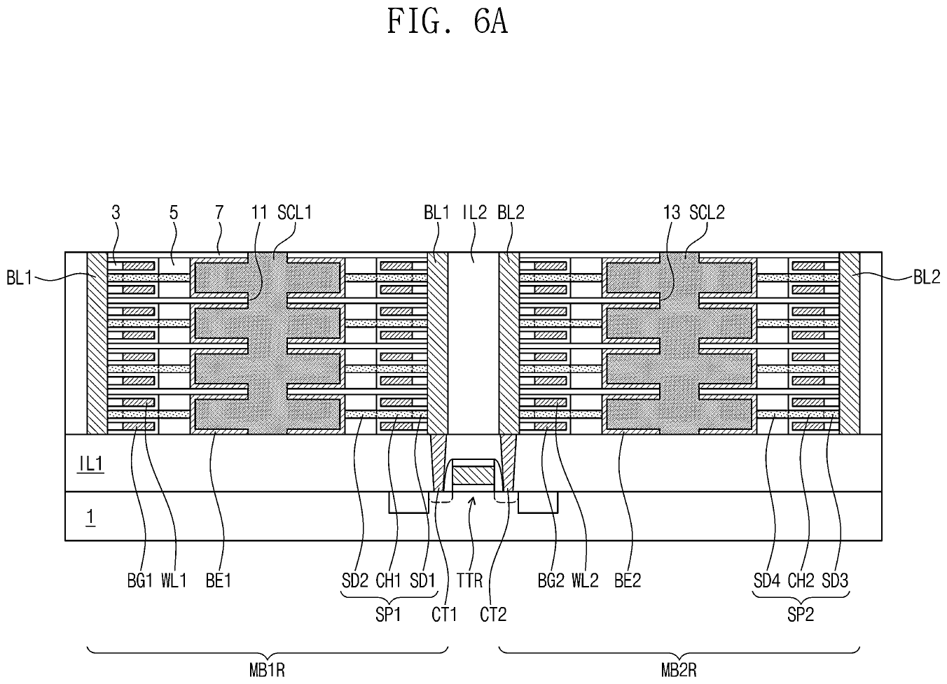

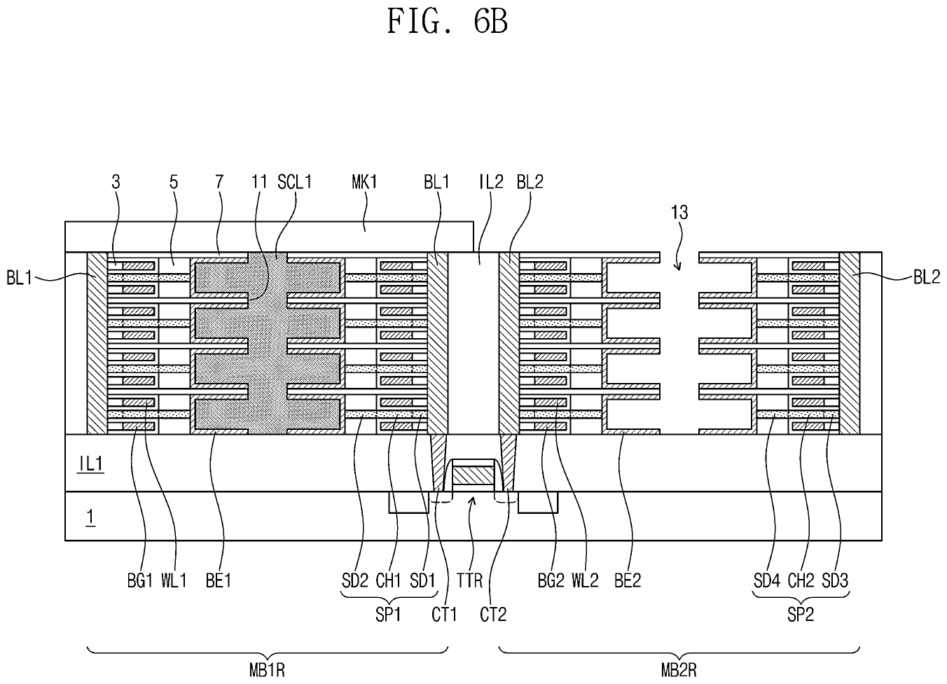

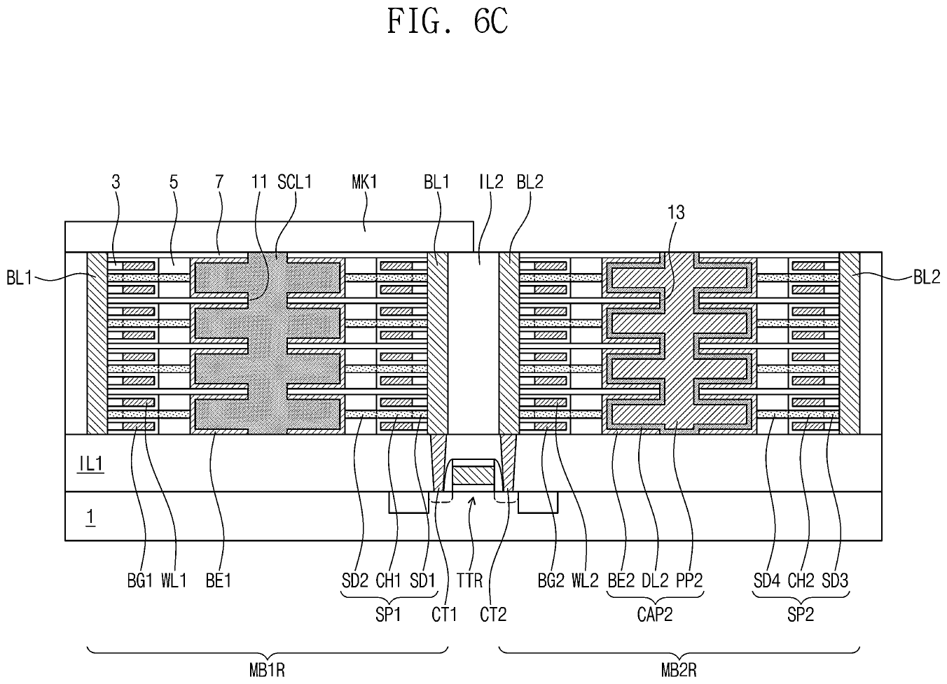

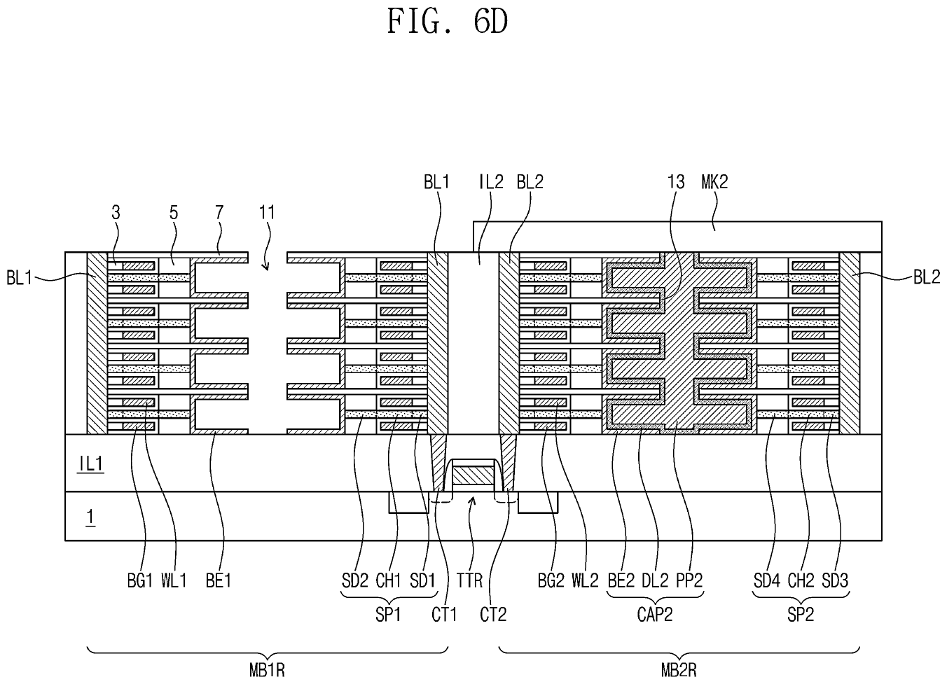

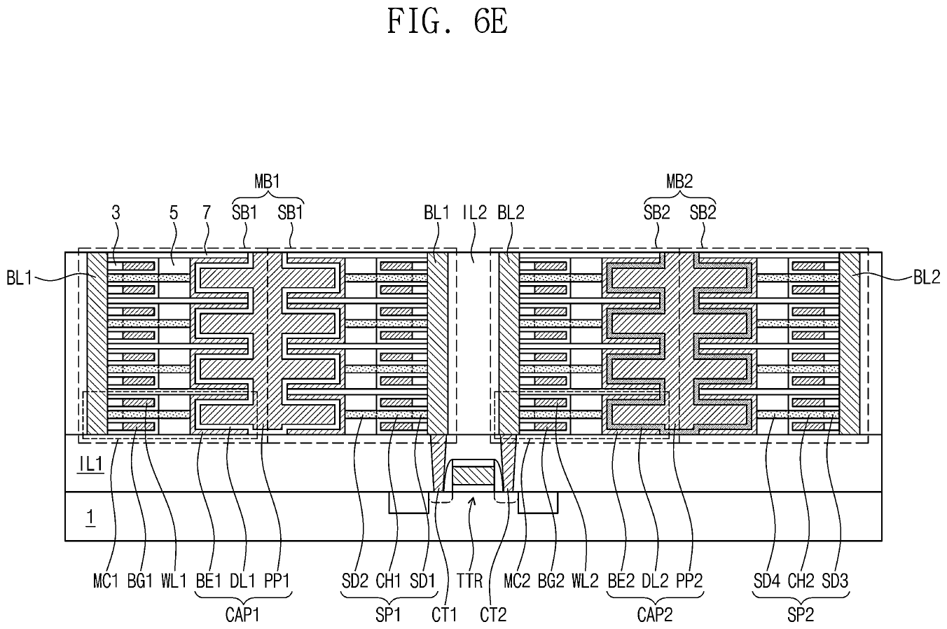

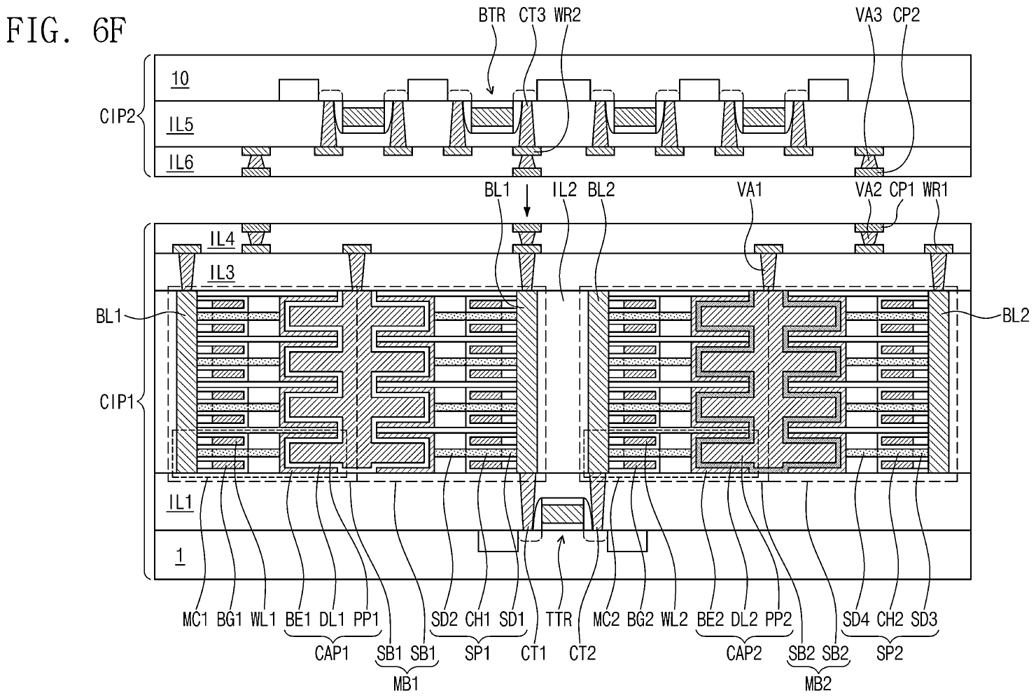

FIGS. 6A to 6F sequentially illustrate a process of manufacturing the semiconductor memory device of FIG. 3.

Referring to FIG. 6A, a first substrate 1 is prepared. The first substrate 1 includes a first memory block region MB1R and a second memory block region MB2R. Transfer transistors TTR are formed on the first substrate 1. The transfer transistors TTR may be disposed between the first memory block region MB1R and the second memory block region MB2R. A first interlayer insulating layer IL1 is formed to cover the transfer transistors TTR. First and second semiconductor patterns SP1 and SP2, first and second word lines WL1 and WL2, and first and second back gate lines BG1 and BG2, gate insulating layer Gox, first to third insulating patterns 3, 5, and 7, first and second unit electrodes BE1 and BE2, first and second bit lines BL1 and BL2, and a second interlayer insulating layer IL2 are formed on the first interlayer insulating layer IL1. The first and second semiconductor patterns SP1 and SP2 may be formed of the same material and at the same height, simultaneously. The first and second word lines WL1 and WL2 and the first and second back gate lines BG1 and BG2 may have the same material and may be formed simultaneously. The first and second bit lines BL1 and BL2 may be formed of the same material and may be formed simultaneously. The first and second unit electrodes BE1 and BE2 may be formed of the same material, at the same height, simultaneously. The term “height” may be used herein with reference to a distance from an underlying substrate 1 in the vertical direction (e.g., D3).

Two first unit electrodes BE1 positioned at one height may be formed to face each other. A first empty space 11 may be formed between the first unit electrodes BE1 and the third insulating patterns 7 in the first memory block region MB1R. A second empty space 13 may be formed between the second unit electrodes BE2 and the third insulating patterns 7 in the second memory block region MB2R. The first empty space 11 is filled with a first sacrificial pattern SCL1. The second empty space 13 is filled with a second sacrificial pattern SCL2. The first sacrificial pattern SCL1 and the second sacrificial pattern SCL2 may be formed of, for example, a spin on hardmask (SOH) or an amorphous carbon layer (ACL).

Referring to FIGS. 6A and 6B, a first mask pattern MK1 is formed on the first memory block region MB1R to cover the first sacrificial pattern SCL1 and the second interlayer insulating layer IL2. The first mask pattern MK1 exposes the second sacrificial pattern SCL2 on the second memory block region MB2R. The second sacrificial pattern SCL2 is removed to expose the second empty space 13. As a result, inner surfaces and ends of the second unit electrodes BE2 and side surfaces of the third insulating patterns 7 adjacent thereto may be exposed. An upper surface of the first interlayer insulating layer IL1 may be exposed at a bottom of the second empty space 13.

Referring to FIGS. 6B and 6C, a second dielectric layer DL2 is conformally covered on a front surface of the first substrate 1 to conformally cover inner and bottom surfaces of the second empty space 13. Accordingly, the second dielectric layer DL2 may be conformally formed on inner surfaces and ends of the second unit electrodes BE2, side surfaces of the third insulating patterns 7 adjacent thereto, and an upper surface of the first interlayer insulating layer IL1. The second dielectric layer DL2 may be formed of a ferroelectric material or an antiferroelectric material. A second common electrode layer is deposited on the front surface of the first substrate 1 to fill the second empty space 13. Then, an anisotropic etching process may be performed on the second common electrode layer and the second dielectric layer DL2 to remove the second common electrode layer and the second dielectric layer DL2 on the uppermost third insulating pattern 7, the second interlayer insulating layer IL2, and the first mask pattern MK1 while leaving the second dielectric layer DL2 in the second empty space 13 to form a second common electrode PP2.

Referring to FIGS. 6C and 6D, the first mask pattern MK1 is removed. A second mask pattern MK2 is formed to cover the second memory block region MB2R. The second mask pattern MK2 exposes the first sacrificial pattern SCL1 on the first memory block region MB1R. The first sacrificial pattern SCL1 is removed to expose the first empty space 11. As a result, inner surfaces and ends of the first unit electrodes BE1 and side surfaces of the third insulating patterns 7 adjacent thereto may be exposed. An upper surface of the first interlayer insulating layer IL1 may be exposed at a bottom of the first empty space 11.

Referring to FIGS. 6D and 6E, a first dielectric layer DL1 is conformally covered on the front surface of the first substrate 1 to conformally cover the inner and bottom surfaces of the first empty space 11. Accordingly, the first dielectric layer DL1 may be conformally formed on inner surfaces and ends of the first unit electrodes BE1, side surfaces of the third insulating patterns 7 adjacent thereto, and an upper surface of the first interlayer insulating layer IL1. The first dielectric layer DL1 may be formed as a single-layer or multi-layer structure of at least one of silicon oxide and/or metal oxide. A first common electrode layer is deposited on the front surface of the first substrate 1 to fill the first empty space 11. Then, an anisotropic etching process may be performed on the first common electrode layer and the first dielectric layer DL1 to remove the first common electrode layer and the first dielectric layer DL1 on the uppermost third insulating pattern 7, the second interlayer insulating layer IL2, and the second mask pattern MK2, while leaving the first dielectric layer DL1 in the first empty space 11, to form a first common electrode PP1. As a result, the first and second memory blocks MB1 and MB2 described with reference to FIG. 3 may be formed.

Referring to FIG. 6F, a third interlayer insulating layer IL3 is formed on the first and second memory blocks MB1 and MB2 and the second interlayer insulating layer IL2. First vias VA1 are formed in the third interlayer insulating layer IL3. First wirings WR1 are formed on the third interlayer insulating layer IL3. Second vias VA2 and first conductive pads CP1 are formed in the third interlayer insulating layer IL3. Accordingly, a first semiconductor chip CIP1 is formed.

Additionally, referring to FIG. 6F, a second semiconductor chip CIP2 is formed. The second semiconductor chip CIP2 may have a structure described with reference to FIG. 3. The second semiconductor chip CIP2 is turned over and placed on the first semiconductor chip CIP1 so that the second conductive pads CP2 are in contact with the first conductive pads CP1. Then, a thermocompression process may be formed to manufacture the semiconductor memory device of FIG. 3.

In the semiconductor memory device according to the inventive concept, as shown in FIG. 6A, the process of manufacturing the first and second unit electrodes BE1 and BE2 on the first substrate 1 in the first and second memory block regions MB1R and MB2R may be the same as each other and may be formed simultaneously, thereby simplifying the process.

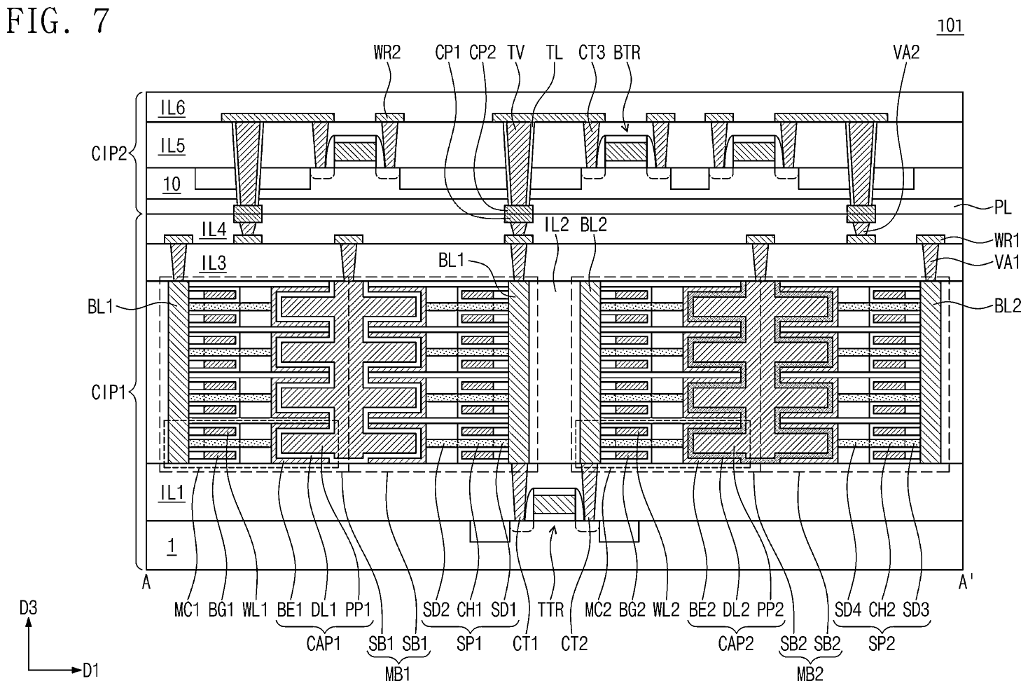

FIG. 7 is a cross-sectional view of a semiconductor memory device according to embodiments of the inventive concept.

Referring to FIG. 7, in a semiconductor memory device 101 according to the present embodiment, a first semiconductor chip CIP1 may have the same structure as described with reference to FIG. 3. In a second semiconductor chip CIP2, bit line selection transistors BTR are disposed on a second substrate 10. Fifth and sixth interlayer insulating films IL5 and IL6 are sequentially stacked on the second substrate 10 and cover the bit line selection transistors BTR. Third contacts CT3 may be disposed in the fifth interlayer insulating layer IL5. A second wiring WR2 is disposed between the fifth and sixth interlayer insulating films IL5 and IL6. A lower surface of the second substrate 10 is covered with a protective layer PL. The protective layer PL is in contact with the fourth interlayer insulating layer IL4 of the first semiconductor chip CIP1. Second conductive pads CP2 are disposed in the protective layer PL. The second conductive pads CP2 are in contact with the first conductive pads CP1 of the first semiconductor chip CIP1, respectively. Through vias TV penetrate the second substrate 10 and the fifth interlayer insulating layer IL5 to connect the second wirings WR2 to the second conductive pads CP2. A via insulating layer TL is interposed between the through vias TV and the second substrate 10. Other structures may be the same/similar to those described with reference to FIG. 3.

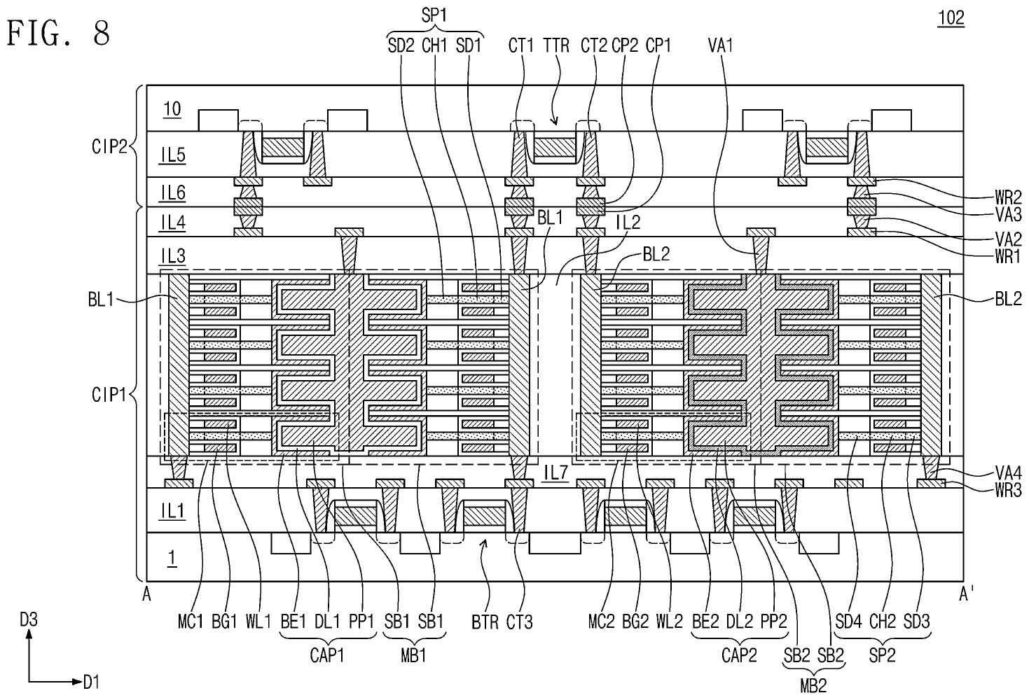

FIG. 8 is a cross-sectional view of a semiconductor memory device according to embodiments of the inventive concept.

Referring to FIG. 8, in a semiconductor memory device 102 according to the present embodiment, a first semiconductor chip CIP1 may include bit line selection transistors BTR, while the second semiconductor chip CIP2 includes transfer transistors TTR. Specifically, the bit line selection transistors BTR are disposed on the first substrate 1. First and seventh interlayer insulating layers IL1 and IL7 are sequentially stacked on the first substrate 1 to cover the bit line selection transistors BTR. Third contacts CT3 are disposed in the first interlayer insulating layer IL1 to be connected to source/drain regions of the bit line selection transistors BTR. Third wirings WR3 are disposed between the first and seventh interlayer insulating layers IL1 and IL7. Fourth vias VA4 are disposed in the seventh interlayer insulating layer IL7. One of the first bit lines BL1 is connected to one of the third contacts CT3 through one of the fourth vias VA4 and one of the third wirings WR3.

First and second memory blocks MB1 and MB2 and a second interlayer insulating layer IL2 are disposed on the seventh interlayer insulating layer IL7. A third interlayer insulating layer IL3 and a fourth interlayer insulating layer IL4 are sequentially stacked on the first and second memory blocks MB1 and MB2 and the second interlayer insulating layer IL2. First vias VA1 may be disposed in the third interlayer insulating layer IL3. First wirings WR1 are disposed between the third interlayer insulating layer IL3 and the fourth interlayer insulating layer IL4. Second vias VA2 are disposed in the fourth interlayer insulating layer IL4. First conductive pads CP1 are disposed on the fourth interlayer insulating layer IL4. Each of the first vias VA1, first wirings WR1, second vias VA2, and first conductive pads CP1 may include a metal such as tungsten, copper, aluminum, ruthenium, tantalum, and titanium.

The second semiconductor chip CIP2 includes a second substrate 10 and transfer transistors TTR disposed on a lower surface thereof. The lower surface of the second substrate 10 may be sequentially covered with fifth and sixth interlayer insulating layers IL5 and IL6. First and second contacts CT1 and CT2 are disposed in the fifth interlayer insulating layer IL5. Second wirings WR2 are disposed between the fifth and sixth interlayer insulating layers IL5 and IL6. Third vias VA3 are disposed in the sixth interlayer insulating layer IL6. Second conductive pads CP2 are disposed at a lower end of the sixth interlayer insulating layer IL6. Each of the third contacts CT3, second wirings WR2, third vias VA3, and second conductive pads CP2 may include a metal such as tungsten, copper, aluminum, ruthenium, tantalum, and titanium. Other structures may be the same/similar to FIG. 3.

The semiconductor memory device according to the inventive concept may include both the first memory block including the DRAM cells and the second memory block including the FeRAM cells, and may have both volatile memory storage characteristics and non-volatile memory storage characteristics. In addition, the semiconductor memory device is capable of fast data processing, has excellent durability, and has excellent power gain characteristics. Additionally, as the first memory block and the second memory block have the same three-dimensional structure, the highly integrated semiconductor memory device may be provided and may be easier to manufacture the same.

It will be understood that spatially relative terms such as ‘top,’ ‘above,’ ‘upper,’ ‘upper portion,’ ‘upper surface,’ ‘bottom,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

While embodiments are described above, a person skilled in the art may understand that many modifications and variations are made without departing from the scope of the inventive concept defined in the following claims. Accordingly, the example embodiments of the inventive concept should be considered in all respects as illustrative and not restrictive, with the scope of the inventive concept being indicated by the appended claims.

What is claimed is:

1. A semiconductor memory device comprising:
a first substrate; and
a first memory block and a second memory block on an upper surface of the first substrate and spaced apart from each other in a first direction,
wherein the first memory block comprises:
first bit lines extending perpendicular to the upper surface of the first substrate, the first bit lines being spaced apart from each other in a second direction intersecting the first direction;
first semiconductor patterns in contact with side surfaces of the first bit lines, the first semiconductor patterns extending in the first direction; and
first capacitors electrically connected to ends of the first semiconductor patterns,
wherein the second memory block comprises:
second bit lines extending perpendicular to the upper surface of the first substrate, the second bit lines being spaced apart from each other in the second direction;
second semiconductor patterns in contact with side surfaces of the second bit lines, the second semiconductor patterns extending in the first direction; and
second capacitors electrically connected to ends of the second semiconductor patterns,
wherein the first capacitors respectively include a first dielectric layer of at least one of silicon oxide or metal oxide, and
wherein the second capacitors respectively include a second dielectric layer of at least one of a ferroelectric material or an antiferroelectric material.

2. The semiconductor memory device of claim 1, further comprising:
transfer transistors on the first substrate;
a first interlayer insulating layer on the first substrate and the transfer transistors and between the first substrate and the first and second memory blocks; and
first contacts in the first interlayer insulating layer and electrically connecting first source/drain regions of the transfer transistors to the first bit lines, respectively; and
second contacts in the first interlayer insulating layer and electrically connecting second source/drain regions of the transfer transistors to the second bit lines, respectively.

3. The semiconductor memory device of claim 2, further comprising:
first conductive pads adjacent an upper surface of the first interlayer insulating layer and in contact with the first contacts and the second contacts, respectively;
a second interlayer insulating layer between the first interlayer insulating layer and the first and second memory blocks;
second conductive pads adjacent a lower surface of the second interlayer insulating layer and in contact with the first conductive pads, respectively;
third contacts in the second interlayer insulating layer and electrically connected to the first bit lines, respectively; and
fourth contacts in the second interlayer insulating layer and electrically connected to the second bit lines, respectively.

4. The semiconductor memory device of claim 1, further comprising:
a second substrate on the first memory block and the second memory block; and
bit line selection transistors on the second substrate and electrically connected to the first bit lines.

5. The semiconductor memory device of claim 4, further comprising:
a first interlayer insulating layer on the first and second memory blocks;
first conductive pads adjacent an upper surface of the first interlayer insulating layer and electrically connected to the first bit lines, respectively;
second conductive pads between the second substrate and the first interlayer insulating layer, wherein the second conductive pads are in contact with the first conductive pads, respectively; and
through vias electrically connecting the second conductive pads to first source/drain regions of the bit line selection transistors.

6. The semiconductor memory device of claim 1, further comprising:
a second substrate on the first memory block and the second memory block;
bit line selection transistors on the first substrate; and
transfer transistors between the second substrate and the first and second memory blocks,
wherein the transfer transistors electrically connect the first bit lines to the second bit lines.

7. The semiconductor memory device of claim 1, wherein the first memory block further comprises first word lines adjacent upper surfaces of the first semiconductor patterns, respectively,
wherein the second memory block further comprises second word lines adjacent upper surfaces of the second semiconductor patterns, respectively, and
wherein the first word lines and the second word lines extend in the second direction.

8. The semiconductor memory device of claim 7, wherein the first memory block further includes first back gate lines adjacent lower surfaces of the first semiconductor patterns, respectively,
wherein the second memory block further includes second back gate lines adjacent lower surfaces of the second semiconductor patterns, respectively, and
wherein the first back gate lines and the second back gate lines extend in the second direction.

9. The semiconductor memory device of claim 1, wherein the first memory block includes a first left sub-block and a first right sub-block that are symmetrical to each other,
wherein each of the first left sub-block and the first right sub-block includes the first bit lines, the first semiconductor patterns, and the first capacitors,
wherein the second memory block includes a second left sub-block and a second right sub-block that are symmetrical to each other,
wherein each of the second left sub-block and the second right sub-block includes the second bit lines, the second semiconductor patterns, and the second capacitors.

10. The semiconductor memory device of claim 1, wherein the first capacitors further respectively include a first unit electrode and a first common electrode spaced apart from each other by the first dielectric layer between the first unit electrode and the first common electrode,
wherein the second capacitors further respectively include a second unit electrode and a second common electrode spaced apart from each other by the second dielectric layer between the second unit electrode and the second common electrode,
wherein the first unit electrode and the second unit electrode respectively have a hollow cup shape,
wherein the first unit electrode and the second unit electrode respectively include a first conductive material,
wherein end portions of the second unit electrode adjacent to the second common electrode include a leaker material portion comprising a leaker material,
wherein an electrical resistance of the leaker material is greater than an electrical resistance of the first conductive material and is less than an electrical resistance of the ferroelectric material or the antiferroelectric material.

11. A semiconductor memory device comprising:
a first substrate;
a first memory block and a second memory block on an upper surface of the first substrate and spaced apart from each other in a first direction; and
transfer transistors on the first substrate and electrically connecting the first memory block to the second memory block,
wherein the first memory block comprises:
first bit lines extending perpendicular to the upper surface of the first substrate, the first bit lines being spaced apart from each other in a second direction intersecting the first direction;
first semiconductor patterns in contact with side surfaces of the first bit lines, the first semiconductor patterns extending in the first direction; and
first capacitors electrically connected to ends of the first semiconductor patterns,
wherein the second memory block comprises:
second bit lines extending perpendicular to the upper surface of the first substrate, the second bit lines being spaced apart from each other in the second direction;
second semiconductor patterns in contact with side surfaces of the second bit lines, the second semiconductor patterns extending in the first direction; and
second capacitors electrically connected to ends of the second semiconductor patterns,
wherein the first capacitors respectively include a first dielectric layer of at least one of silicon oxide or metal oxide, and
wherein the second capacitors respectively include a second dielectric layer of at least one of a ferroelectric material or an antiferroelectric material.

12. The semiconductor memory device of claim 11, further comprising:
a first interlayer insulating layer on the first substrate and the transfer transistors and between the first substrate and the first and second memory blocks; and
first contacts in the first interlayer insulating layer and electrically connecting first source/drain regions of the transfer transistors to the first bit lines, respectively; and
second contacts in the first interlayer insulating layer and electrically connecting second source/drain regions of the transfer transistors to the second bit lines, respectively.

13. The semiconductor memory device of claim 12, further comprising:
first conductive pads adjacent an upper surface of the first interlayer insulating layer and in contact with the first contacts and the second contacts, respectively;
a second interlayer insulating layer between the first interlayer insulating layer and the first and second memory blocks;
second conductive pads adjacent a lower surface of the second interlayer insulating layer and in contact with the first conductive pads, respectively;
third contacts in the second interlayer insulating layer and electrically connected to the first bit lines, respectively; and
fourth contacts in the second interlayer insulating layer and electrically connected to the second bit lines, respectively.

14. The semiconductor memory device of claim 11, further comprising:
a second substrate on the first memory block and the second memory block; and
bit line selection transistors on the second substrate and electrically connected to the first bit lines.

15. The semiconductor memory device of claim 14, further comprising:
a first interlayer insulating layer on the first and second memory blocks;
first conductive pads adjacent an upper surface of the first interlayer insulating layer and electrically connected to the first bit lines;
second conductive pads between the second substrate and the first interlayer insulating layer, wherein the second conductive pads are in contact with the first conductive pads, respectively; and
through vias electrically connecting the second conductive pads to first source/drain regions of the bit line selection transistors.

16. The semiconductor memory device of claim 11, wherein the first memory block further includes first word lines adjacent upper surfaces of the first semiconductor patterns,
wherein the second memory block further includes second word lines adjacent upper surfaces of the second semiconductor patterns, and
wherein the first word lines and the second word lines extend in the second direction.

17. The semiconductor memory device of claim 16, wherein the first memory block further includes first back gate lines adjacent lower surfaces of the first semiconductor patterns,
wherein the second memory block further includes second back gate lines adjacent lower surfaces of the second semiconductor patterns, and
wherein the first back gate lines and the second back gate lines extend in the second direction.

18. A semiconductor memory device comprising:
a first substrate;
a first memory block and a second memory block on an upper surface of the first substrate and spaced apart from each other in a first direction;
transfer transistors on the first substrate and electrically connecting the first memory block to the second memory block;
a second substrate on the first memory block and the second memory block; and
bit line selection transistors on the second substrate,
wherein the first memory block comprises:
first bit lines extending perpendicular to the upper surface of the first substrate and electrically connected to the bit line selection transistors, the first bit lines being spaced apart from each other in a second direction intersecting the first direction;
first semiconductor patterns in contact with side surfaces of the first bit lines, the first semiconductor patterns extending in the first direction;
first word lines adjacent upper surfaces of the first semiconductor patterns;
first gate insulating layers between the first semiconductor patterns and the first word lines, respectively; and
first capacitors electrically connected to ends of the first semiconductor patterns,
wherein the second memory block comprises:
second bit lines extending perpendicular to the upper surface of the first substrate, the second bit lines being spaced apart from each other in the second direction;
second semiconductor patterns in contact with side surfaces of the second bit lines, the second semiconductor patterns extending in the first direction;
second word lines adjacent upper surfaces of the second semiconductor patterns;
second gate insulating layers between the second semiconductor patterns and the second word lines, respectively; and
second capacitors electrically connected to ends of the second semiconductor patterns,
wherein the first capacitors respectively include a first dielectric layer of at least one of silicon oxide or metal oxide, and
wherein the second capacitors respectively include a second dielectric layer of at least one of a ferroelectric material or an antiferroelectric material.

19. The semiconductor memory device of claim 18, wherein the first memory block further includes first back gate lines adjacent lower surfaces of the first semiconductor patterns,
wherein the second memory block further includes second back gate lines adjacent lower surfaces of the second semiconductor patterns, and
wherein the first back gate lines and the second back gate lines extend in the second direction.

20. The semiconductor memory device of claim 18, wherein the first capacitors further respectively include a first unit electrode and a first common electrode spaced apart from each other by the first dielectric layer between the first unit electrode and the first common electrode,
wherein the second capacitors further respectively include a second unit electrode and a second common electrode spaced apart from each other by the second dielectric layer between the second unit electrode and the second common electrode,
wherein the first unit electrode and the second unit electrode respectively have a hollow cup shape,
wherein the first unit electrode and the second unit electrode respectively include a first conductive material,
wherein ends of the second unit electrode adjacent to the second common electrode include a leaker material portion comprising a leaker material,
wherein an electrical resistance of the leaker material is greater than an electrical resistance of the first conductive material and is less than an electrical resistance of the ferroelectric material or the antiferroelectric material.
